(19) United States
(12) Patent Application Publication
(10) Pub. No.: US 2010/0255196 A1
(43) Pub. Date: Oct. 7, 2010

(54) TREATMENT SYSTEM FOR FLAT SUBSTRATES

(75) Inventors: Michael Geisler, Wachtersbach (DE); Thomas Merz, Aschaffenburg (DE); Mario Roder, Gelnhausen (DE)

Correspondence Address: CANTOR COLBURN, LLP, 20 Church Street, 22nd Floor, Hartford, CT, 06103, US

(73) Assignee: LEYBOLD OPTICS GMBH, Alzenau (DE)

(21) Appl. No.: 12/599,429

(22) PCT Filed: Apr. 28, 2008
(86) PCT No.: PCT/EP08/03414

§ 371 Date: Jun. 8, 2010

(30) Foreign Application Priority Data
May 9, 2007 (DE) 10 2007 022 252.3
May 10, 2007 (DE) 10 2007 022 431.3

(51) Int. Cl. C23C 16/453; B05C 13/02; C23C 14/00

(52) U.S. Cl. 427/248.1; 118/723 R; 118/503; 118/50

(57) ABSTRACT

A reactor for the treatment of flat substrates includes a vacuum chamber with a process space arranged therein. A first electrode and a counterelectrode generate a plasma for the treatment of a surface to be treated and form two opposite walls of the process space. The reactor further includes means for introducing and means for removing gaseous material into and out from the process space. At least one substrate is accommodated by a front side of the counterelectrode. The vacuum chamber includes an opening having a closure device. The reactor includes a device for varying the relative distance between the first electrode and the counterelectrode and a device assigned to the counterelectrode for accommodating substrates. At least one substrate is arranged at an angle alpha in a range of between 0° and 90° relative to a perpendicular direction at least during the performance of the treatment.

### TECHNICAL FIELD

The invention relates to treatment systems for substrates and, more particularly, to a reactor for treating flat substrates.

### BACKGROUND

EP 0312447 B1 has already disclosed a method for producing thin layers on substrates for electronic or optoelectronic use of one plasma deposition process (PECVD), wherein, in the presence of a deposition plasma, reaction gases for producing the layers are introduced into a plasma box arranged in a vacuum chamber. In this case, a pressure which is lower than that which prevails in the plasma box is generated and maintained in the vacuum chamber. Similar methods are also known from EP 02218112 B1 and U.S. Pat. No. 4,798,739. Further reactors, in particular comprising a plurality of chambers for the treatment of a substrate, are disclosed in DE 19901426 A1, U.S. Pat. No. 6,183,564 B1, U.S. Pat. No. 5,944,857, and also in the Japanese patent abstract JP 06267808 A.

The abovementioned PECVD method, which is used for the cost-effective production of solar cells with a high efficiency and wherein silane and hydrogen are used as process gases, has, as important deposition parameters, the gas pressure, the gas flow rate, the power density and frequency of the plasma excitation, the substrate temperature, the gas composition and also the distance between electrode and counterelectrode. In order to achieve high deposition rates, high gas flow rates and a reduction of the electrode distance are of importance here. In this case, favorable distances between the electrodes are in ranges between 0.5 and 15 mm. With such small distances, the introduction of the substrates into the space between the electrodes poses a problem, where it should be taken into consideration that ensuring high productivity with uninterrupted layer growth during coating necessitates parallel processing, for the realization of which cluster installations are used, which require a high structural outlay in the case of the substrate sizes of 1.4 m² or more that are desired nowadays.

Central clusters are already known, wherein parallel-processing chambers are arranged around a central point, at which a central handling device is situated. What is disadvantageous about central cluster systems is that, in the case of large substrates, the central handling device becomes very large and not very accessible and that the number of process chambers and hence the throughput that can be achieved are limited. Vertical cluster installations are furthermore known, which are used in the production of TFT displays, for example. Vertical cluster systems comprise a tower-like architecture with flat process chambers, as a result of which effective gas separation between the components becomes difficult and the number of layers constructed one on top of another is limited.

### BRIEF SUMMARY

The disclosure enables efficient plasma treatment of flat substrates, in particular the disclosure provides a corresponding reactor and a method for the treatment of flat substrates, and furthermore enables simple and reliable handling of flat substrates and also improved production of treated substrates.

The reactor according to the invention for the treatment of flat substrates comprising a vacuum chamber with a process space arranged therein, wherein a first electrode and a counterelectrode are provided for generating a plasma for the treatment of a surface to be treated and form two opposite walls of the process space, and means for introducing and means for removing gaseous material, in particular coating or cleaning material, into and/or from the process space, wherein the at least one substrate can be accommodated by the counterelectrode on the latter's front side facing the electrode, and a loading and unloading opening of the vacuum chamber, preferably with a closure device, is distinguished by the fact that provision is made of a device for varying the relative distance between the electrodes, wherein provision is made of a first, relatively large distance when loading or unloading the process chamber with the at least one substrate and a second, relatively small distance when carrying out the treatment of the at least one substrate, and/or provision is made of a device which is assigned to the counterelectrode and is intended for accommodating substrates, which is embodied in such a way that the at least one substrate is arranged at an angle alpha in a range of between 0° and 90° relative to the perpendicular direction at least during the performance of the treatment, in particular the coating, preferably also during the loading or unloading of the process space, with the surface to be treated facing downward. In the context of the invention, the term flat substrates denotes, in particular, substrates for solar cells, glass panes or the like. Rectangular substrates of 1.4 m² or more are typical. In the context of the invention, the term treatment denotes any manner of modifying a substrate by means of a plasma generated between two flat electrodes, but in particular a PECVD method.

Electrode and counterelectrode can advantageously be brought comparatively close together by means of the device for varying the distance, wherein the distance between the electrode and the substrate also decreases. As a result, the layer construction can advantageously be positively influenced during coating. It is conceivable to vary the distance and thus the process parameters during the treatment of the substrate as well, in order to supervise the treatment process. It goes without saying that in the case of varying the distance, either the electrode or the counterelectrode or both can be moved.

Furthermore, the substrate can advantageously be arranged at an angle alpha in a range of between 0° and 90° relative to the perpendicular direction during the performance of the treatment, with the surface to be treated facing downward. This reduces the risk of particle contamination of the sensitive substrate surface that is to be treated or has been treated, since fewer particles can reach said surface. Such particles arise if layers formed in the process space, for example layers composed of silicon, become chipped. Values of the angle alpha of 1°, 3°, 5°, 7°, 9°, 11°, 13°, 15°, 17°, 20°, 25°, 30°, 40°, 45° are preferred since the horizontal space requirement for the reactor is thereby reduced.

In the case of the handling device according to the invention for flat substrates comprising at least one gripping arm module for one or a plurality of substrates, it is provided that the gripping arm module is embodied in such a way that the substrates can be moved parallel to the surface thereof and are arranged at an angle alpha in a range of between 0° and 90° relative to the perpendicular direction at least during the loading and unloading of a process space with a surface to be treated oriented downward. Contamination of the surface that is to be treated or has been treated while the substrates are handled is advantageously reduced by the substrates being arranged at an angle alpha in a range of between 0° and 90° relative to the perpendicular direction with a surface to be treated facing downward.

In further accordance with an exemplary embodiment, preference is given to a a control, sensors and a drive, and a position of a substrate relative to the electrode and/or counterelectrode of the reactor is determined by means of the sensors, and loading or unloading of the reactor or the vacuum chamber is carried out by means of control and drive.

A further aspect of the invention provides a device for processing flat substrates comprising a transport space extending along a longitudinal direction, at least one process container for the treatment of flat substrates, which is connected or can be connected to the transport space, and a transport robot for transporting substrates, which transport robot can be moved along the longitudinal direction, wherein it is provided that the process container and/or the transport robot are embodied in such a way that the substrates are arranged with the surface to be treated at an angle alpha in a range of between 0° and 90° relative to the perpendicular direction at least during a predefined time interval, preferably during the performance of any treatment of the substrates in the process container. The substrates are advantageously arranged at an angle alpha in a range of between 0° and 90° relative to the perpendicular direction at least during a predefined time interval, preferably during the performance of a treatment the substrates in the process container or during the loading or unloading of the process container, with the surface to be treated facing downward, since, by this means, the contamination of the surface to be treated or of the treated surface can be reduced and, at the same time, the space requirement during the processing of the flat substrates can be kept relatively small. In this case, preference is given to a mount for the substrates without carriers (transport frames), since the latter are costly and unstable in the event of thermal loading. A certain stiffness of the substrates which permits the latter to stand on an edge is assumed in the case of such a mount.

A further aspect of the invention provides a method for the treatment of flat substrates in a reactor comprising a vacuum chamber with a process space arranged therein, wherein a first electrode and a counterelectrode are provided for generating a plasma for the treatment of a surface to be treated and form two opposite walls of the process space, and means for introducing and means for removing gaseous material, in particular coating or cleaning material, into or from the process space, wherein the relative distance between the electrodes is adjustable, and provision is made of a first, relatively large distance when loading or unloading the process chamber with the at least one substrate and a second, relatively small distance when carrying out the coating of the at least one substrate, and/or wherein the at least one substrate is arranged at an angle alpha in a range of between 0° and 90° relative to the perpendicular direction at least during the performance of the treatment, in particular the coating, preferably also during the loading or unloading of the process space, with the surface to be treated facing downward.

A further aspect of the invention relates to a method for processing flat substrates with a transport space extending along a longitudinal direction, at least one process container for the treatment of flat substrates, which is assigned to the transport space, and a transport robot for transporting substrates, which transport robot can be moved along the longitudinal direction, wherein the process container and/or the transport robot make it possible for the substrates to form with the surface to be treated at an angle alpha in a range of between 0° and 90° relative to the perpendicular direction at least during a predefined time interval, preferably during the performance of any treatment of the substrates in the process container.

The invention is described in greater detail below with reference to drawings, which also reveal further features, details and advantages of the invention independently of the summary in the patent claims.

### BRIEF DESCRIPTION OF THE DRAWINGS

FIG. 1 shows a longitudinal section of a reactor with two electrodes in plan view, wherein the electrodes are situated at a reduced distance from one another;

FIG. 2 shows a longitudinal section of a reactor analogously to the illustration in FIG. 1, but additionally with a pump channel;

FIG. 3 shows the view of the reactor shown in FIG. 2, wherein the electrodes are situated at an increased distance from one another and a substrate has been partly introduced into the reactor;

FIG. 4 shows a longitudinal section of a counterelectrode and of a housing wall of a reactor in side view with a perpendicular direction L;

FIG. 5 shows a gripping arm of a handler device for flat substrates in lateral plan view;

FIG. 6 shows a three-dimensional illustration of a handler assembly with a frame rack and two shafts;

FIG. 7 shows a section of a processing line in plan view;

FIG. 8 shows a three-dimensional illustration of a processing line;

FIG. 9 shows a three-dimensional illustration of details of a processing line;

FIG. 10 shows a section of a processing line with a shuttle; and

FIG. 11 shows a longitudinal section of a double processor space reactor in plan view.

### DETAILED DESCRIPTION

The following explanation of reactors, handling, devices and methods for processing flat substrates will focus on structural aspects, where it is obvious to the person skilled in the art that these devices and methods are provided with sensors, heating and cooling units, control units and drives that are not specifically illustrated.

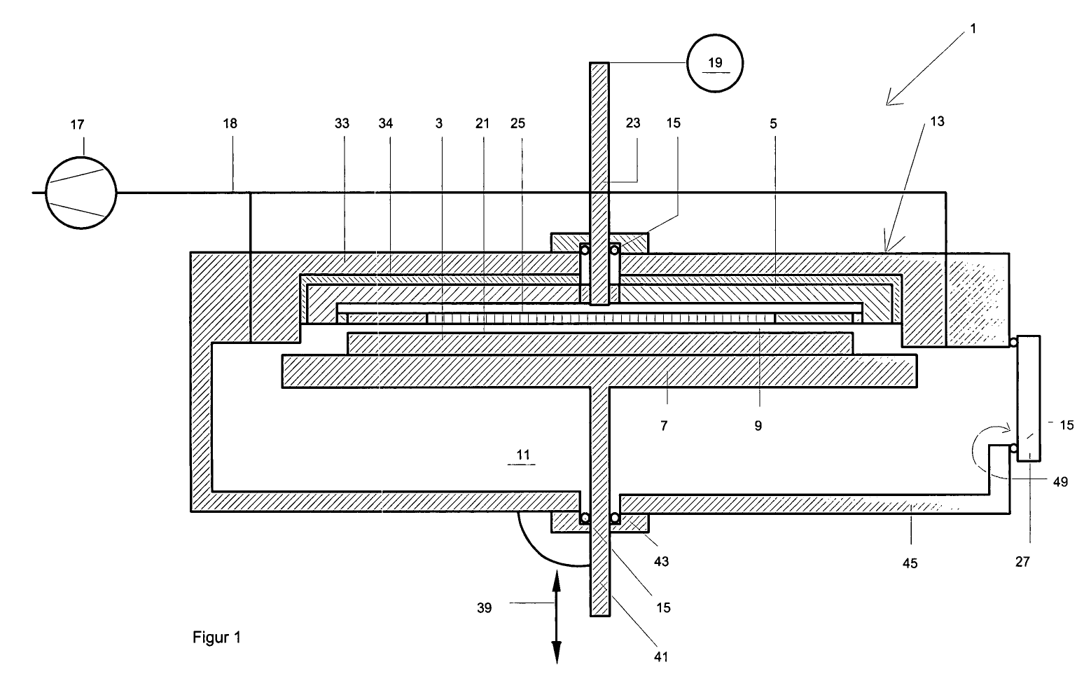

FIG. 1 shows, in a simplified illustration, a reactor 1 for the treatment of flat substrates 3. The reactor 1 can be designed as a PECVD reactor, for example. The reactor 1 comprises a process space 9 with an electrode 5 and a counterelectrode 7, which are designed for generating a plasma for the treatment of a surface to be treated of one or a plurality of flat substrates 3. The electrodes 5, 7 can be connected, or may have been connected, to a voltage source not illustrated in greater detail, preferably a radio-frequency supply source, in order to generate an electric field in the process space 9. The electrodes 5, 7 are preferably designed for the treatment of substrates with an area of at least 1.4 m² as a treatment or processing step in the production of high-efficiency thin-film solar modules, for example amorphous or microcrystalline silicon thin-film solar cells.

The electrodes 5, 7 form two opposite walls of the process space 9. The process space 9 is situated in a vacuum chamber 11 having a loading and unloading opening 49, which can be closed by means of a closure device 27. The closure device is optional. The vacuum chamber 11 is formed by a housing 13 of the reactor 1. Seals 15 are provided for the purpose of sealing off from the surroundings.

The vacuum chamber 11 can have any desired spatial form, for example with a round or polygonal, in particular rectangular, cross section. The process space 9 is embodied as a flat parallelepiped, for example.

For introducing and for removing gaseous material, means that are known per se are provided, wherein the gaseous material is coating or cleaning material, in particular. The cleaning material can be NF3, for example. The introduction and removal of the gaseous material can be effected both sequentially and in parallel.

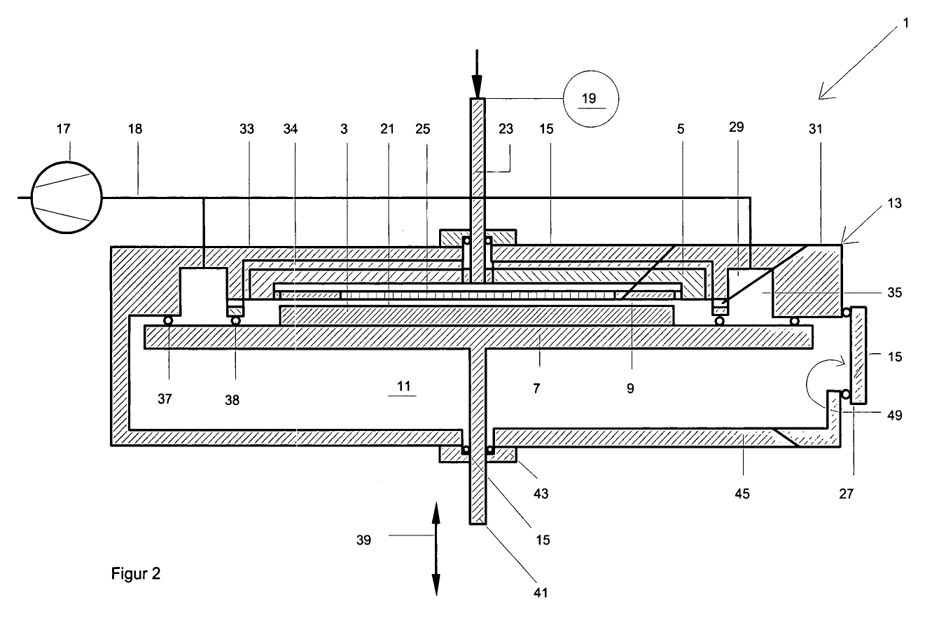

In FIGS. 1 and 2, a vacuum pump 17 and assigned vacuum lines 18 are illustrated as means for removing gaseous material. A coating material source 19 with a channel 23, which are connected to a gas distributor 25, are provided as means for introducing gaseous material. In the present embodiment, the gas distributor 25 is embodied in a manner similar to a shower and comprises a multiplicity of perforations which open into the process space 9 and through which gaseous material is introduced into the process space 9. It goes without saying that the means for introducing gaseous material can also be embodied differently than in the illustration in FIG. 1, as can the gas distributor 25.

According to the invention, the reactor 1 has a device for varying the relative distance between the electrodes, which device, in the embodiment in FIGS. 1 to 3, is embodied as a sliding bolt 41 which, by means of a bearing plate 43, can perform a linear movement in the vacuum chamber 11. The sliding bolt is connected to the rear side of the counterelectrode 7, said rear side being remote from the electrode 5. A drive assigned to the sliding bolt 41 is not illustrated.

The electrode 5 is arranged in a holding structure in the vacuum chamber 11, which is formed by the housing rear wall 33 in the illustration in FIGS. 1 to 3. For this purpose, the electrode 5 is accommodated in a cutout of the holding structure and separated from the vacuum chamber wall by a dielectric 34. The substrate 3 is accommodated by the counterelectrode 7 on the latter's front side facing the electrode 5.

It can be seen in the illustration in FIG. 1 that the counterelectrode 7 covers the cutout during the performance of the treatment. In this case, a gap is formed between an edge region of the counterelectrode 7 and an edge region of the cutout, said gap having a width of the order of magnitude of 1 mm. The gap width is dimensioned such that a plasma can be held in the interior of the process space during the performance of the treatment. The gap has the effect that an excessively large pressure gradient is not established between the process space and the rest of the interior of the vacuum chamber 11. By means of the vacuum lines 18, regions of the vacuum chamber 11 which are arranged outside the process space 9 are connected to the vacuum pump 17, such that during operation of the vacuum pump 17, on account of the larger volume, it is possible to achieve a high homogeneity of the gas flows from the process space 9 via the gap in a simple manner. It goes without saying that other configurations of the means for removing gaseous material from the process space are also encompassed by the invention.

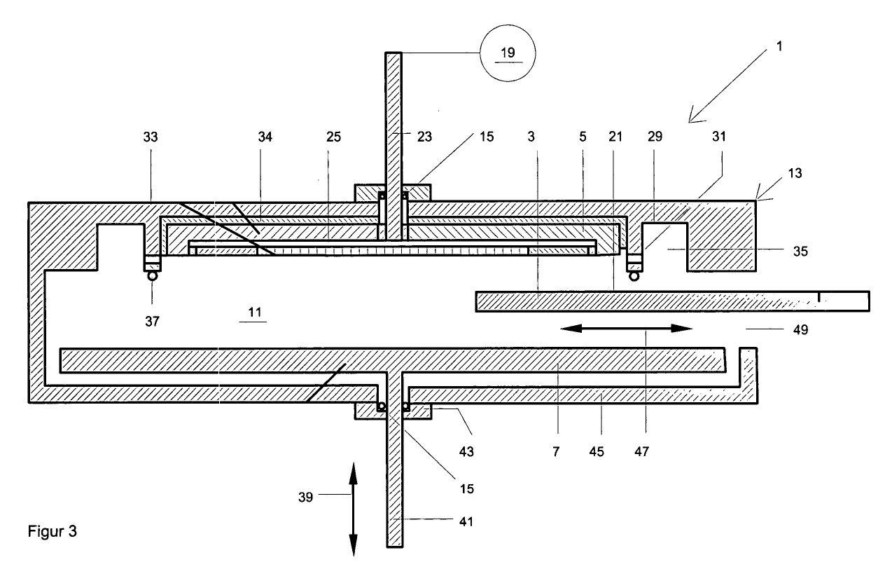

FIGS. 2 and 3 show a further reactor 1, analogously to the reactor 1 illustrated in FIG. 1. Only the differences are discussed below.

The reactor 1 in accordance with FIGS. 2 and 3 has a, circumferential, pump channel 29, formed by a groove-type second cutout in the holding structure. Upstream, the pump channel 29 is connected to the process space 9 via evacuating channels 31. Downstream, the pump channel 29 is furthermore connected to the vacuum pump 17 via vacuum lines 18. The pump channel is separated or can be separated from the vacuum chamber 11 in a gas-tight manner in the case where the cutouts are covered by the counterelectrode 7. Thermally resistant seals 37 are provided for this purpose. Covering is effected during the performance of the treatment of the flat substrate. This advantageously permits a relatively high working pressure of up to 10 mbar in the process space 9 relative to a working pressure of 10⁻² to 10⁻⁴ mbar in the process chamber during performance of the treatment.

According to the invention, a further embodiment provides for the counterelectrode 7 to have a device (not illustrated in FIGS. 1 to 3) for accommodating flat substrates, which is embodied in such a way that the substrate or substrates is or are arranged at an angle alpha in a range of between 0° and 90° relative to the perpendicular direction at least during the performance of the treatment of the surface that is to be treated or has been treated, in a manner oriented downward. With such an arrangement of a substrate, contaminations of the substrate surface that is to be coated or has been coated can be avoided or at least reduced since the relevant particles move away downward in the gravitational field and thus away from the surface at risk. A value of the angle alpha of 1°, 3°, 5°, 7°, 9°, 11°, 13°, 15°, 17°, 20°, 25°, 30°, 40°, 45° is preferred.

In FIG. 3, no closure device 27 is illustrated, and the substrate 3 has been partly introduced into the process space 9 of the reactor 1 through the opening 49. A double-headed arrow 47 indicates the loading and unloading movement direction of the substrate 3. It can be discerned that, by virtue of the counterelectrode that has been pulled back and is situated near the housing wall 45 of the housing 13, the substrate 3 can be introduced into the process space 9 in a particularly simple manner since almost the entire spatial extent of the vacuum chamber 11 is available for this purpose.

After the substrate 3 has been introduced into the reactor 1, the substrate 3 can be accommodated by the counterelectrode 7 on the latter's front side facing the electrode 5.

The device for accommodating substrates can be designed for substrates which are provided with a carrier.

In one embodiment of the invention, the device for accommodating substrates is designed for framelessly accommodating one or a plurality of substrates or for frameless carriers.

The device for accommodating substrates can furthermore be designed forchanging the distance between the substrate that is to be accommodated or has been accommodated and the surface of the front side of the counterelectrode. In particular, the substrate can be at a greater distance from said surface of the counterelectrode during the loading or unloading of the process space than during the performance of a treatment.

The device for accommodating substrates can have at least one upper holding element for one or a plurality of substrates at least in an upper edge region of the counterelectrode 7 and at least one lower holding element for one or a plurality of substrates at least in a lower region of at least the counterelectrode 7.

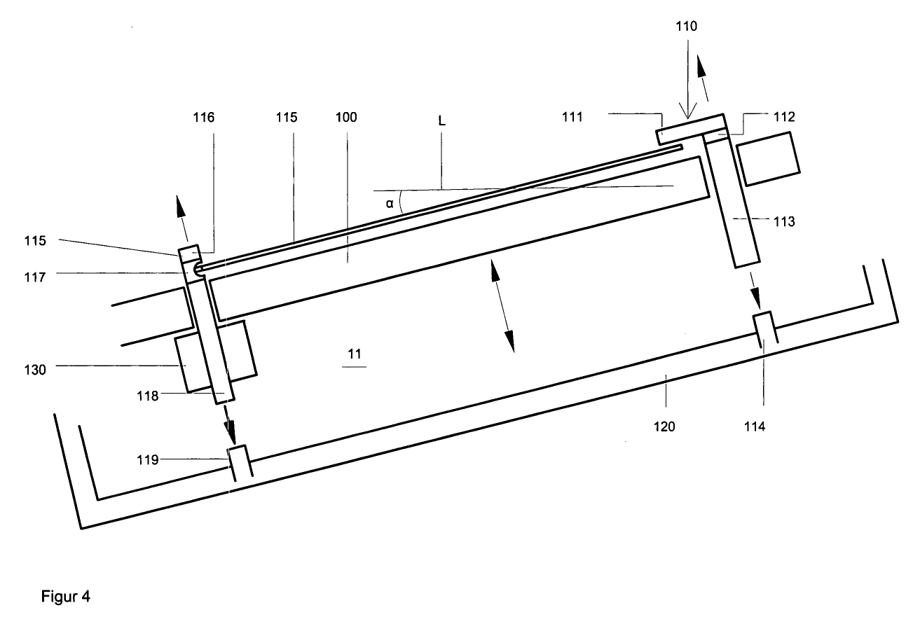

FIG. 4 illustrates a longitudinal section of a counterelectrode 100 and of a housing wall 120 of a reactor according to the invention in side view with a perpendicular direction L, with a substrate 105 arranged at an angle alpha in a range of between 0° and 90° relative to the perpendicular direction with the surface to be treated oriented downward. An electrode arranged opposite the counterelectrode is not illustrated.

The lower holding element is embodied as a bearing element 115 for the lower edge of a substrate 105. In this case, the bearing element 115 is embodied as a bolt 118 with a metallic bearing part 116, which projects into the process space (not illustrated in FIG. 4), with an intermediate piece 117, composed of a ceramic, wherein the bolt extends through a bushing in the counterelectrode 100 into a region of the vacuum chamber 11 on the rear side of the counterelectrode 120. The end region of the bolt 118 can press against a stop 119 when the counterelectrode 100 is pulled back in the direction of the housing wall 120, and can thus be moved from the front-side surface of the counterelectrode 100 in the direction of the process space. The lower edge of the substrate 105 is thus moved away from the front-side surface of the counterelectrode 120 and said substrate therefore assumes a greater distance from said surface. At least parts of the bolt 118 are surrounded by a protective enclosure 130, which can be filled with an inert gas, for example nitrogen, and increases the corrosion protection in this region, which is advisable particularly when highly corrosive cleaning agents are introduced.

The upper holding element is embodied as a counterbearing 110 with a metallic counterbearing part 111 for an upper edge region of the substrate 105. The counterbearing is connected to a bolt 113 extending through a bushing in the counterelectrode 100 into a region of the vacuum chamber 11 on the rear side of the counterelectrode 100. Furthermore, an intermediate piece 112, preferably composed of a ceramic, is provided between counterbearing part 111 and the bolt 113. The bolt 113 can press against a stop 114 when the counterelectrode 100 is pulled back in the direction of the housing wall 120, and in the process can perform a movement relatively from the front-side surface of the counterelectrode 100. The distance between the substrate 105 and the front-side surface of the counterelectrode 100 can thus be increased. By means of the illustrated change in the distance between the substrate 105 and the surface of the front side of the counterelectrode 100, reliable loading and unloading of the process space becomes achievable since the substrate is spatially freed relative to the surface of the front side of the counterelectrode 100 during loading and unloading.

In one embodiment of the invention, furthermore, if the counterelectrode 100 is moved in the direction of the electrode for example in order to perform the treatment of a substrate, the holding elements which can be moved linearly relative to the surface of the front side of the counterelectrode are pressed against one or a plurality of stops situated for example in a coating-free edge region of a cutout in which the electrode is arranged. The distance between substrate and surface of the front side of the counterelectrode is thus reduced; the substrate is advantageously pressed against said surface, such that it is possible to achieve a fixing of the position of the substrate during the performance of the treatment. In a further embodiment of the invention, as an alternative or in addition, one or a plurality of holding elements is or are assigned to one or both side regions of the substrate.

Furthermore, the holding elements can be movable in a pivotable manner relative to the surface of the front side of the counterelectrode in order thus to facilitate a loading or unloading movement of the substrate.

Since defined potential conditions in the process space are important at least during the treatment, in particular during the performance of a coating, the holding elements are embodied in electrically floating fashion.

In the case of the handling device according to the invention for flat substrates comprising at least one gripping arm module, the gripping arm module is embodied in such a way that the substrates are arranged at an angle alpha in a range of between 0° and 90° relative to the perpendicular direction during the loading and unloading, of a process space for example, with a surface to be treated or a treating surface oriented downward. The angle alpha has a value of 1°, 3°, 5°, 7°, 9°, 11°, 13°, 15°, 17°, 20°, 25°, 30°, 40°, 45°.

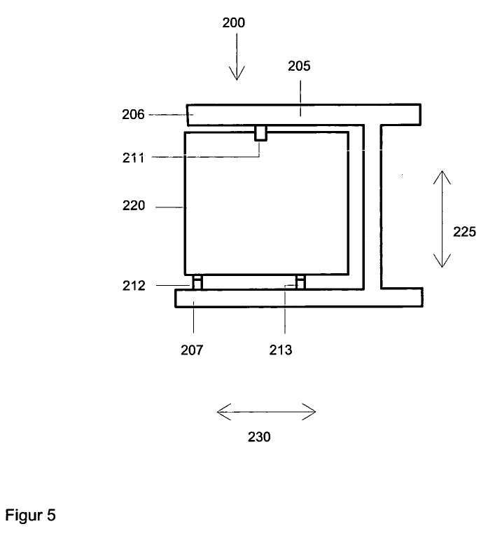

FIG. 5 illustrates a gripping arm 200 comprising a frame rack 205 having an upper and a lower fork prong 206, 207. A counterbearing 211 is provided on the upper fork prong 206 and supports 212 and 213 for a substrate 220 mounted on the gripping arm 200 are provided on the lower fork prong 207. The gripping arm 200 enables frameless mounting of the substrate 220, wherein the latter is arranged in a manner standing on one of its lower edges. The frame rack can be moved vertically parallel to the arrow 225 and horizontally parallel to the arrow 230 by drives. By means of the vertical movement, the substrate 220 can be placed onto at least one lower holding element of a mount for substrates or be picked up therefrom.

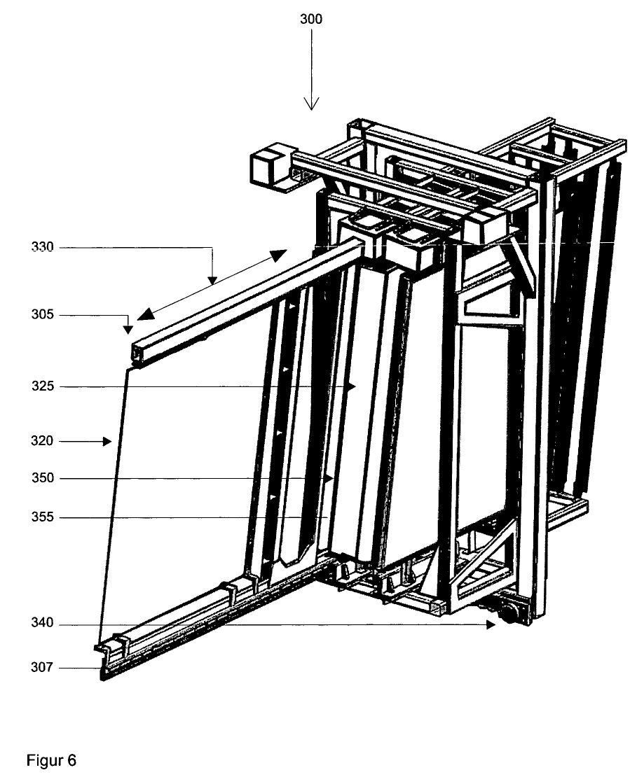

FIG. 6 shows a handler assembly 300 with a frame rack 305 and a shaft 350 in a perspective illustration.

The frame rack can be inserted into the shaft 350 and withdrawn therefrom parallel to the direction of the arrow 330. Furthermore, the handler assembly 300 has a second shaft 355 with a further frame rack (not visible). Analogously to the illustration in FIG. 5, a substrate 320 is arranged in the region between the fork prong 306 and the fork prong 307. Furthermore, the handler has a heating component 325 for the temperature regulation of substrates at least frame rack 305 inserted into the shaft 350. The handler assembly furthermore has wheels 340 used to ensure its movability. In addition to a movement of the frame rack 305 parallel to the direction of the arrow 330, a vertical movement of the frame rack 305 is possible. The drive units required for carrying out the movement of the frame rack are not illustrated in FIGS. 5 and 6.

The handling device according to the invention is assigned to a reactor according to the invention. In this case, the process space of the reactor is loaded or unloaded through a combination of a movement of the gripping arm parallel to the surface of the substrate to be introduced into the process space or to be removed therefrom, in a horizontal or vertical direction. As was described with reference to FIG. 4, during loading or unloading, the distance between the substrate and the surface of the front side of the counterelectrode is kept relatively large and the substrate is placed onto at least one lower holding element of the device for accommodating substrates or is picked up from the lower holding element.

In the case of a handling device comprising a first and a second gripping arm, a substrate treated in a reactor can be exchanged for a second substrate in a simple manner. In this case, a first substrate is unloaded from the reactor and introduced into the handling device, and a second substrate, already present in the handling device, is subsequently introduced into the reactor. In this case, only a movement of the handling device relative to the reactor is necessary in order to ensure a correct positioning of the gripping arm with respect to the loading and unloading opening.

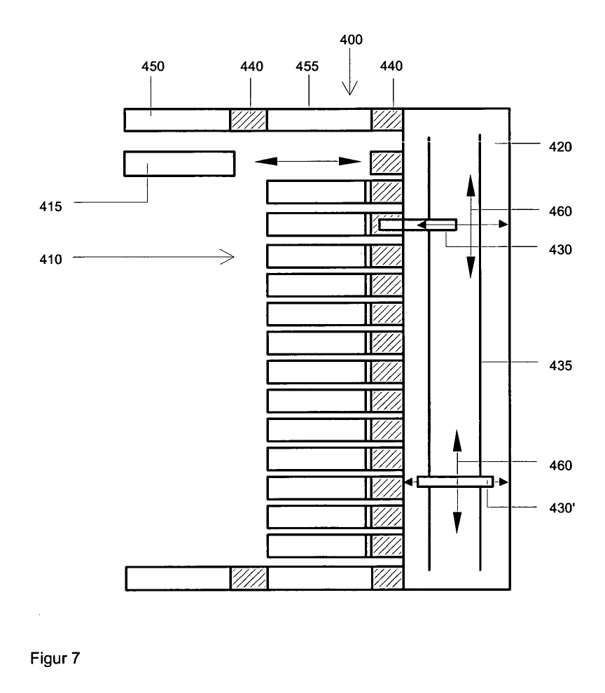

A device according to the invention for processing flat substrates is illustrated in a sectional illustration in plan view in FIG. 7.

In this case, FIG. 7 shows a processing line 400 with a transport space, embodied as tunnel 420, with a series of process containers embodied as reactors 410 and serving for the treatment of flat substrates, which are connected to the tunnel 420.

Situated in the, temperature-regulated, tunnel 420 is a robot 430, which, for clarification, is also illustrated at a second position in the tunnel 420, where it is designated by the reference symbol 430′. The robot 430 is arranged on a guide rail 435. Furthermore, two heating modules 450 and 455 are provided at the input of the processing line, wherein the heating module 450 enables heating at atmospheric pressure, for example. The process containers or reactors 410 are connected to the tunnel by valves 440. The tunnel 420 can be evacuated and/or can be filled with an inert gas, for example nitrogen or argon or the like. A reactor separate from the tunnel is designated by 415.

A processing line as in FIG. 7 is suitable in particular for processing substrates for thin-film solar cells. Such a thin-film solar cell comprises P-i-n-layers composed of amorphous silicon and P-I-N-layers composed of microcrystalline silicon. The doping layers and the intrinsic layers are preferably deposited in different process containers in order to prevent entrainment of dopants that might adversely influence the efficiency of the intrinsic layers. The processing line illustrated enables highly effective parallel processing.

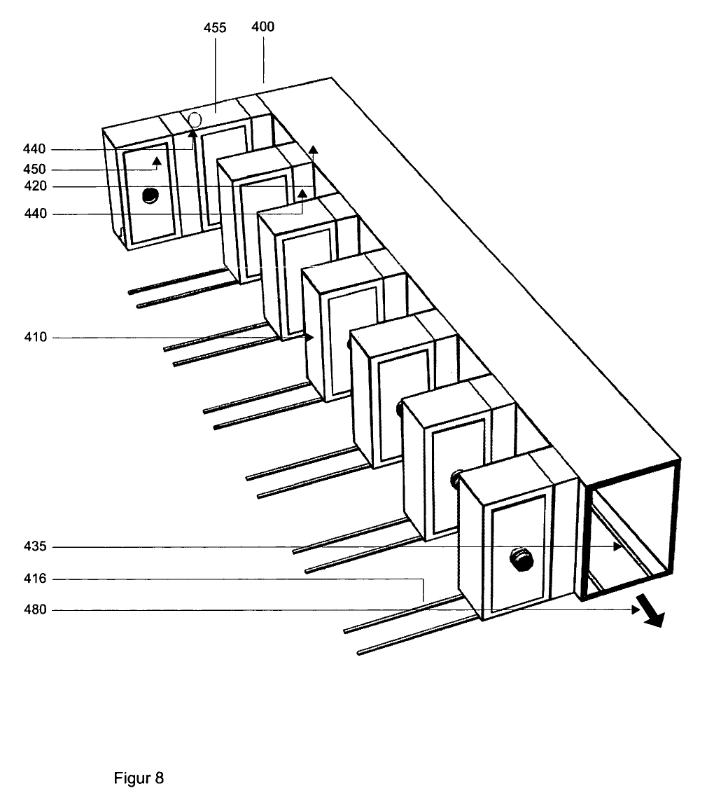

FIG. 8 shows a three-dimensional illustration of the processing line from FIG. 7, where it can be discerned that the reactors 410, embodied as modules that can be coupled and decoupled, are arranged such that they can be moved on rails 416, in order to minimize a stoppage of the processing line. In the event of maintenance or in the case of a disturbance, the reactors can be decoupled from the tunnel without interrupting the remaining processes.

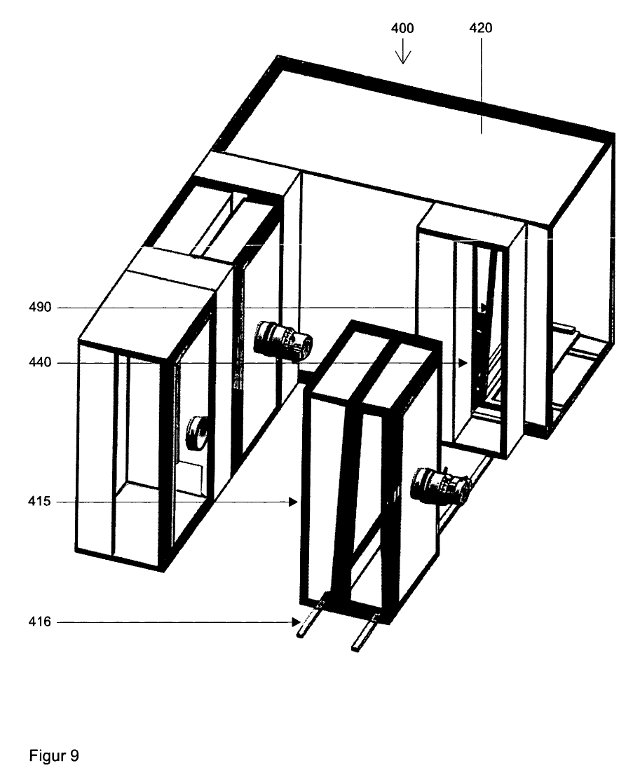

In FIG. 9, a state with a decoupled reactor 415 is illustrated in greater detail for a processing line 400. For clarification, the valve 440 is open here, such that a substrate 490 situated on a robot in the tunnel can be discerned.

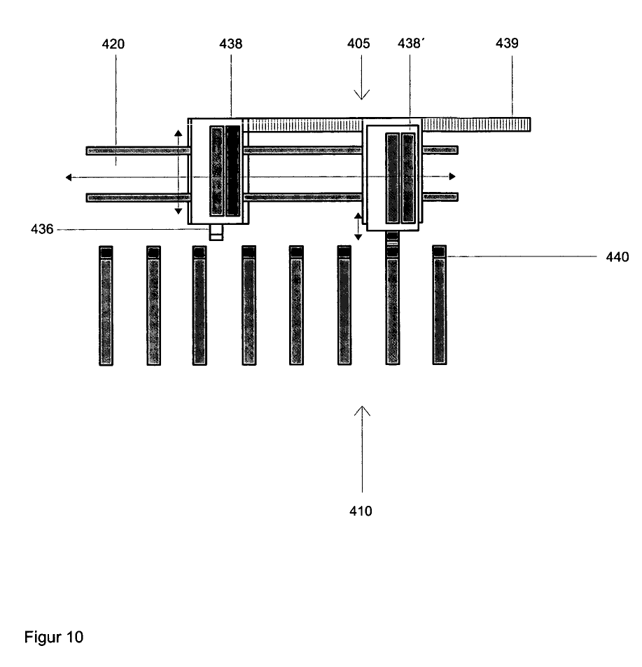

FIG. 10 illustrates a further embodiment of the device according to the invention for processing flat substrates, wherein the transport robot is embodied as a shuttle 438 or 438′ with a vacuum container and, arranged therein, a handling device for flat substrates. The shuttle has a valve 436, by means of which it can be connected to the process container 410 in terms of vacuum engineering. In the case of this embodiment of the invention, the transport space is preferably embodied such that it cannot be evacuated. Such an embodiment of the invention is suitable for very large substrates, in particular, since the volume to be evacuated can be kept small. In order to connect the shuttle 438 to power and media supplies, a drag chain 439 can be provided. In one preferred embodiment, the shuttle 438 has a dedicated, preferably smaller, pump stand that is arranged with the vacuum container on a baseplate, for example. When the shuttle 438 or the vacuum container is coupled to a process container, the intermediate volume situated between the two valves can be evacuated by means of a suitable pump or by means of a metering valve by means of the shuttle pump possibly present.

It is advantageous, if sensors are provided, to determine the relative position of the handler arranged in the vacuum container and/or substrates assigned thereto with respect to the electrode or counterelectrode in a process container. A correct coupling for the loading and unloading of the process container with a substrate can then be controlled by means of a control.

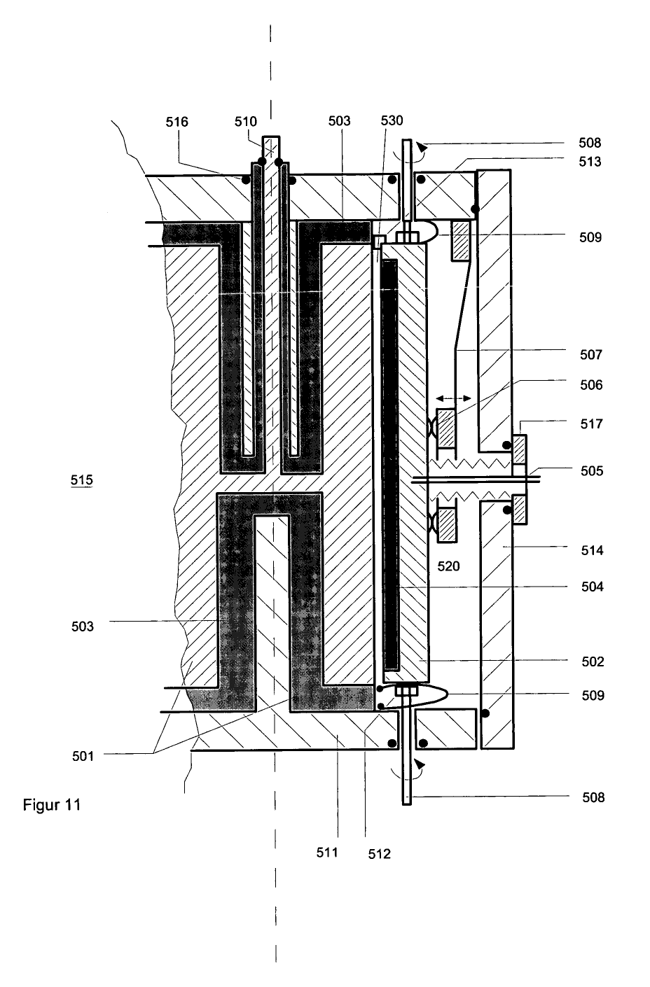

FIG. 11 illustrates in a sectional illustration in plan view a further reactor for the treatment of flat substrates, comprising a first vacuum chamber 520, in which a first process space 530 is arranged, comprising a first electrode 501 and a first counterelectrode 502 for generating a plasma for the treatment of a surface to be treated, wherein the first electrode 501 and the first counterelectrode 502 form two opposite walls of the process space 520.

Furthermore, provision is made of a device for varying the relative distance between the electrodes, wherein provision is made of a first, relatively large distance when loading or unloading the process space 520 with a substrate and a second, relatively small distance when carrying out the treatment of the at least one substrate.

The device for varying the relative distance between the electrodes comprises eccentrics 512, by means of which rotary drives 508 can bring about a parallel displacement of the counterelectrode 502. Furthermore, disk springs 506 are provided, which permit a wobbling movement of the counterelectrode 502, wherein the wobbling movement is limited by the eccentric drives 512. Furthermore, provision is made of a device which is assigned to the counterelectrode and is intended for accommodating substrates, which is analogous to the device already illustrated, but is not shown in detail in FIG. 11.

The reactor 500 furthermore comprises a second vacuum chamber, in which a second process space is arranged, wherein provision is made of a second electrode and a second counterelectrode for generating a plasma for the treatment of a surface to be treated, which respectively form two opposite walls of the second process space. The second vacuum chamber with the second process space is embodied analogously to the first vacuum chamber with the first process space and is arranged on the rear side of the first electrode, that is to say on that side of the first electrode which is opposite relative to the first counterelectrode. Preferably, the second vacuum chamber is embodied in mirror-inverted fashion with respect to the first vacuum chamber. The second vacuum chamber furthermore comprises a device for varying the distance between electrode and counterelectrode. Furthermore, the reactor 500 comprises a radio-frequency feed 510, a housing strip 511, a ceramic stop 513, a housing door 514 and also seals 516 and vacuum bellows 517.

1-38. (canceled)

39. A reactor for the treatment of flat substrates with a coating material, the reactor comprising;
a vacuum chamber with a process space arranged therein, the vacuum chamber including a first electrode and a counterelectrode configured for generating a plasma for the treatment of a surface to be treated, the first electrode and counterelectrode forming two opposing walls of the process space;
a holding structure arranged within the vacuum chamber, the holding structure including a cutout, the first electrode being arranged in the cutout;
means for introducing and means for removing at least one of a gaseous coating material and a gaseous cleaning material from the process space,
wherein the at least one substrate can be accommodated by the counterelectrode on the latter's front side facing the electrode;
a loading and unloading opening of the vacuum chamber, the loading and unloading opening including a closure device,
wherein provision is made of a device for varying the relative distance between the electrodes, wherein provision is made of a first, relatively large distance when loading or unloading the process chamber with the at least one substrate and a second, relatively small distance when carrying out the treatment of the at least one substrate; and
wherein the counterelectrode covers the cutout during the performance of the treatment, wherein a gap is formed between an edge region of the counterelectrode and an edge region of the cutout, said gap being dimensioned such that a plasma generated in the process space is held within the process space, and the vacuum chamber is connected to a vacuum pump in a region arranged outside the process space.

40. A reactor for the treatment of flat substrates with a coating material, the reactor comprising
a vacuum chamber with a process space arranged therein, the vacuum chamber including a first electrode and a counterelectrode for generating a plasma for the treatment of a surface to be treated, the first electrode and the counterelectrode forming two opposing walls of the process space, the vacuum chamber including a loading and unloading opening, the loading and unloading opening including a closure;
means for introducing and means for removing at least one of a gaseous coating material and gaseous cleaning material into and from the process space,
wherein the at least one substrate can be accommodated by the counterelectrode on the latter's front side facing the electrode; and
a device for accommodating at least one substrate assigned to the, the device positioning the at least one substrate at an angle alpha having a value of at least one of 3°, 5°, 7°, 9°, 11°, 13°, 15°, 17°, 20°, 25° and 30° relative to a perpendicular direction at least during the performance of the treatment, in particular the coating, and during the loading or unloading of the process space, with the surface to be treated facing downward.

41. The reactor according to claim 2, wherein the vacuum chamber is assigned a handling device for loading and unloading the process space with at least one substrate, wherein the handling device positions the at least one substrate at an angle alpha in a range of between 0° and 90° relative to the perpendicular direction at least during the loading and unloading of the process space, with the surface to be treated facing downward.

42. The reactor according to claim 2, wherein the device for accommodating the at least one substrate includes a carrier frame configured to framelessly accommodate the at least one substrate.

43. The reactor according to claim 2, wherein the device for accommodating the at least one substrate is configured and disposed to change a distance between the at least one substrate and the surface of the front side of the counterelectrode, wherein the at least one substrate is at a greater distance from said surface of the counterelectrode during the loading or unloading of the process space than during the performance of the treatment.

44. The reactor according to claim 2, wherein the device for accommodating the at least one substrate includes at least one upper holding element for retaining the at least one substrate at least in an upper edge region and at least one lower holding element for retaining the at least one substrate at least in a lower region.

45. The reactor according to claim 6, wherein the at least one upper holding element comprises a counterbearing for retaining the upper edge region of the at least one substrate.

46. The reactor according to claim 6, wherein the lower holding element comprises a bearing element for retaining the lower edge of the at least one substrate.

47. The reactor according to claim 6, wherein at least one of the upper and lower holding element is selectively moveable in at least one of a linear fashion and a pivoting fashion relative to said surface of the counterelectrode.

48. The reactor according to claim 6, wherein at least one of the upper holding element and lower holding element is configured to change a distance between the at least one substrate and the surface of the counterelectrode.

49. The reactor according to claim 5, wherein the device for accommodating the at least one substrate includes components composed of metal arranged in the process space and are at least one of electrically floating and electrically insulated with respect to the counterelectrode and components that are in contact with a plasma in the process space.

50. A handling device for flat substrates comprising: at least one gripping arm module for retaining at least one substrate the gripping arm module being configured and disposed to move the at least one substrate parallel to the surface thereof, the at least one gripping arm positioning the at least one substrate at an angle alpha in a range of between 0° and 90° relative to a perpendicular direction at least during the loading and unloading of a process space with a surface to be treated facing downward, wherein the gripping arm module is associated with a shaft, the gripping arm module being insertable and withdrawn from the shaft along an axis parallel to the surface of the substrate.

51. The handling device according to claim 13, wherein the at least one gripping arm module includes a carrier frame for mounting the at least one substrate.

52. The handling device according to claim 13, wherein the at least one gripping arm module is configured for frameless mounting of the at least one substrate, wherein the at least one substrate is arranged on a lower edge.

53. The handling device according to claim 13, wherein the at least one griping arm module comprises a frame rack having an upper fork prong and a lower fork prong, wherein the upper fork prong includes at least one upper holding element and the lower fork prong includes at least one lower holding element for retaining the at least one substrate.

54. The handling device according to claim 16, wherein the at least one upper holding element comprises a counterbearing for retaining upper edge regions of the at least one substrate and the at least one lower holding element comprises a bearing element for retaining the lower edge of the at least one substrate.

55. A device for processing flat substrates comprising a transport space extending along a longitudinal direction, at least one process container for the treatment of flat substrates, the at least one process container being assigned to a transport space, and a transport robot for transporting substrates, the transport robot being moveable along the longitudinal direction, wherein the transport robot comprises shuttle having a vacuum container including a handling device for flat substrates.

56. The device according to claim 19, further comprising: at least one sensor configured to determine a relative position of the handling device arranged in the vacuum container and flat substrates assigned thereto relative to at least one of an electrode and a counterelectrode.

57. The device according to claim 19, wherein the process container comprises a module that is selectively coupled with the shuttle.

58. The device according to claim 19, wherein the transport space comprises a transport tunnel configured to be evacuated and filled with at least one of an inert gas and a pure atmosphere.

59. A method for the treatment of flat substrates with a coating material, the method comprising:
positioning at least one flat substrate in a process space of a vacuum chamber between a first electrode and a counterelectrode, the at least one flat substrate including a surface to be treated;
generating a plasma between the first electrode and the counterelectrode, the plasma being directed at the surface to be treated;
introducing a gaseous coating material into the process space;
adjusting a relative distance between the first electrode and the counterelectrode between a first, relatively large distance when loading or unloading the process space with the at least one substrate and a second, relatively small distance when introducing the coating material;
positioning the at least one substrate in a holding structure in the vacuum chamber, the holding structure including a cutout, the first electrode being arranged in the cutout;
treating the surface to be treated with the coating material, counterelectrode covers the cutout during the performance of the treatment; and
forming a gap between an edge region of the counterelectrode and an edge region of the cutout, said gap being dimensioned such that the plasma generated in the process space is held within the process space, and the vacuum chamber is connected to a vacuum pump in a region arranged outside the process space.
